(19) United States
(12) Patent Application Publication
(10) Pub. No.: US 2007/0029880 A1
(43) Pub. Date: Feb. 8, 2007

(54) Computer power supply and cable

(76) Inventor: Jinseok Kim, Downey, CA (US)

Correspondence Address: JONATHAN Y. KANG, ESQ.;LEE, HONG, DEGERMAN, KANG & SCHMADEKA, 801 S. Figueroa Street, 14th Floor, Los Angeles, CA, 90017, US

(21) Appl. No.: 11/198,377

(22) Filed: Aug. 4, 2005

(51) Int. Cl. H05K 1/02

(52) U.S. Cl. 307/42

(57) ABSTRACT

A power supply apparatus is disclosed to provide power to a plurality of electrical components inside a computer housing. The power supply apparatus comprises a power supply module to convert electrical power to at least one power level. At least one power distribution panel is disposed within the computer housing. At least one wiring harness is electrically coupled at a first end of the at least one wiring harness to the at least one power distribution panel. The at least one wiring harness at a second end connects to the power supply module to transfer the at least one power level to the at least one power distribution panel. The at least one power distribution panel provides electrical adapters to transfer the at least one power level to cables that are coupled between the electrical adaptors and the plurality of electrical components.

### FIELD OF THE INVENTION

The present invention relates to a power supply. More particularly, the invention relates to a method and apparatus for distributing power from a computer power supply to connect to electronic components within the computer in order to reduce wire and/or cable clutter.

### BACKGROUND OF THE INVENTION

Related art power supplies are large and occupy large amounts of space within an electrical device housing. FIG. 1 illustrates a related art power supply within an electrical device housing.

As shown, a related art power supply 10 occupies a large amount of area within an electrical device housing 25, such as a desktop or laptop computer. These related art power supplies have disadvantages. For example, the related art power supply 10 reduces the available volume for inserting electrical components, which results in increased clutter and decreased electrical packing density within the electrical device housing 25. In yet another example, the related art power supply 10 has its volume occupied by long wires 20 connecting to electrical components 30, at a side of the related art power supply 10, and wires to electrical components 50, located at a bottom of the related art power supply 10, thereby preventing heat transfer from the electrical components 30 and 50 to outside the electrical device housing 25. Furthermore, conventional cooling fans may not properly circulate air to cool electronic components, such as electrical components 30 and 50, that are within an electrical device housing 25 due to clutter created by long wires 20. In addition, noise emitted by conventional cooling fans may be higher due to higher rotational speed needed because of decreased heat dissipation resulting from wire clutter.

Consequently, there is a need for an improved power supply for an electrical device housing that occupies a smaller volume, provides less wire and/or cable clutter and creates other advantages over the related art power supplies.

### SUMMARY OF THE INVENTION

Features and advantages of the invention will be set forth in the description, which follows, and in part will be apparent from the description, or may be learned by practice of the invention. The objectives and other advantages of the invention will be realized and attained by the structure particularly pointed out in the written description and claims hereof as well as the appended drawings.

One objective of the present invention is to reduce the emitted noise from a power supply apparatus when a cooling fan is running. Another objective of the present invention is to reduce wire or cable clutter within a computer housing.

In one embodiment, a power supply apparatus is disclosed to provide power to a plurality of electrical components inside a computer housing. The power supply apparatus comprises a power supply module to convert electrical power to at least one power level. At least one power distribution panel is disposed within the computer housing. At least one wiring harness is electrically coupled at a first end of the at least one wiring harness to the at least one power distribution panel. A second end of the at least one wiring harness connects to the power supply module to transfer the at least one power level to the at least one power distribution panel. The at least one power distribution panel provides electrical adapters to transfer the at least one power level to cables that are coupled between the electrical adaptors and the plurality of electrical components.

In another embodiment, a method is disclosed that provides power to a plurality of electrical components while decreasing cable and/or wire clutter within an electrical housing. The method comprises converting electrical power to at least one power level using a power supply module. The method further comprises electrically coupling at least one power distribution panel to a first end of at least one wiring harness.

The method further comprises electrically coupling a second end of the at least one wiring harness to the power supply module for transferring the at least one power level through the at least one wiring harness to electrical adaptors disposed within the at least one power distribution panel. The method further comprises coupling electrical cables between the plurality of electrical components and the electrical adaptors for transferring the at least one power level from the power supply module to the plurality of electrical components.

One objective of the present invention is to reduce wire and/or cable clutter within an electrical housing. Another objective of the present invention is to reduce the length of wires and/or cables and to reduce the number of loose wires and/or cables within the electrical device housing. Still another objective is to centrally locate power within a computer at one or more distribution points to reduce wire and/or cable clutter when connecting to a plurality of electrical components. Yet another objective is to increase airflow over electrical components within a computer housing through reducing wire and/or cable clutter.

Additional features and advantages of the invention will be set forth in the description, which follows, and in part will be apparent from the description, or may be learned by practice of the invention. It is to be understood that both the foregoing general description and the following detailed description of the present invention are exemplary and explanatory and are intended to provide further explanation of the invention as claimed.

These and other embodiments will also become readily apparent to those skilled in the art from the following detailed description of the embodiments having reference to the attached figures, the invention not being limited to any particular embodiments disclosed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

Features, elements, and aspects of the invention that are referenced by the same numerals in different figures represent the same, equivalent, or similar features, elements, or aspects in accordance with one or more embodiments.

FIG. 1 illustrates a related art power supply in an electronic device housing.

FIG. 2 illustrates a front view of a power supply and a wiring harness cable within an electrical device housing in accordance with one embodiment of the present invention.

FIG. 3 illustrates a top view of a wiring harness cable and a power distribution panel having multiple electrical adaptors in accordance with one embodiment of the present invention.

FIG. 4 illustrates a first and a second power distribution panel connected to a first sub-wiring harness cable and a second sub-wiring harness cable, respectively, in accordance with one embodiment of the present invention.

FIG. 5 illustrates a method of performing power distribution in an electrical device housing in accordance with one embodiment of the present invention.

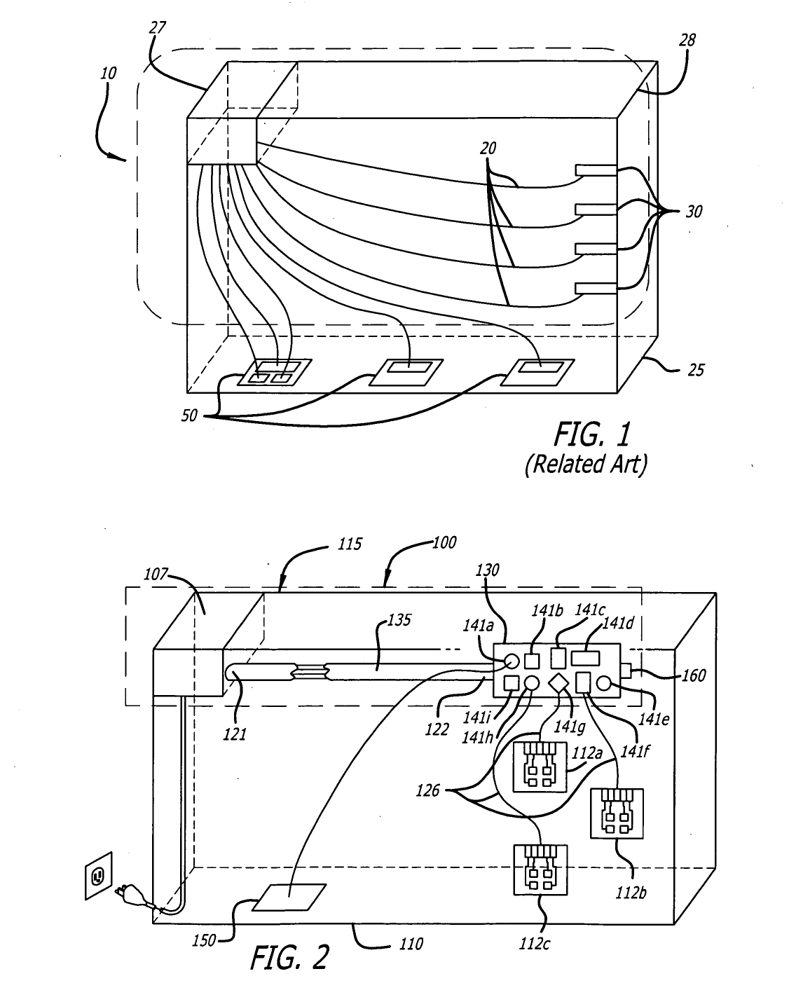

### DETAILED DESCRIPTION OF THE PREFERRED EMBODIMENTS

The present invention relates to a computer power supply. More particularly, the invention relates to a computer power supply having improved properties and reduced size requirements.

Although the invention is illustrated with respect to a computer power supply, it is contemplated that the invention may be utilized wherever there is a desire for efficiently compacting a power supply used for any electrical power housing, while minimizing a volume occupied by the power supply. Reference will now be made in detail to the preferred embodiments of the present invention, examples of which are illustrated in the accompanying drawings.

Referring to FIG. 2, a power supply apparatus 100 provides power to electrical components, for example circuit cards 112a, 112b and 112c, inside of a computer housing 110. A power supply module 107 converts electrical power, such as incoming electrical power, to at least one power level. In one example, the power supply 107 converts an ac power level to one or more dc power levels. The power supply module 107 is preferably, in one example, a switching power supply.

The power distribution panel 130 is preferably located at a first end 122 of a wiring harness 135. The wiring harness 135 electrically couples, preferably at a second end 121 of the wiring harness 135, to the power supply module 107 for transferring the dc power level to the power distribution panel 130. The power distribution panel 130 distributes electrical power to various electrical components. The power distribution panel 130 may be located anywhere within the computer housing 110 to reduce clutter, such as wire and/or cable clutter, within the electrical housing 110. The power distribution panel 130, for example, reduces the length of cables, for example cables 126, required to supply power to electrical components, for example circuit cards 112a-c, which results in reduced cable clutter within the computer housing 110.

Furthermore, the cables, for example cables 126, are only provided when an electrical connection is required between a circuit card, such 112a, and the power distribution panel 130, thereby preventing loose, unconnected cables being present within the computer housing 110. In addition, the power distribution panel 130 distally located from the power supply 107 allows the power supply 107 to occupy a smaller space to provide more free space within the computer housing 110. As a result of a reduction of loose, unconnected cables being present in the computer housing 110, a cooling fan may, with lower rotational speed, provide better air flow circulation within the cooling housing. The lower rotational fan speed will result in reduced emitted fan noise.

The power distribution panel 130 further provides electrical adapters 141a-ito distribute electrical power to multiple electrical components, for example, circuit cards 112a-c. The electrical adaptors 141a-ipreferably comprise multiple types and sizes. In addition, the electrical adaptors 141a-imay comprise multiple plug-in cable connectors. In one preferred embodiment, the electrical adaptors 141a-i are integrally formed and monolithically integrated within the power distribution panel 130.

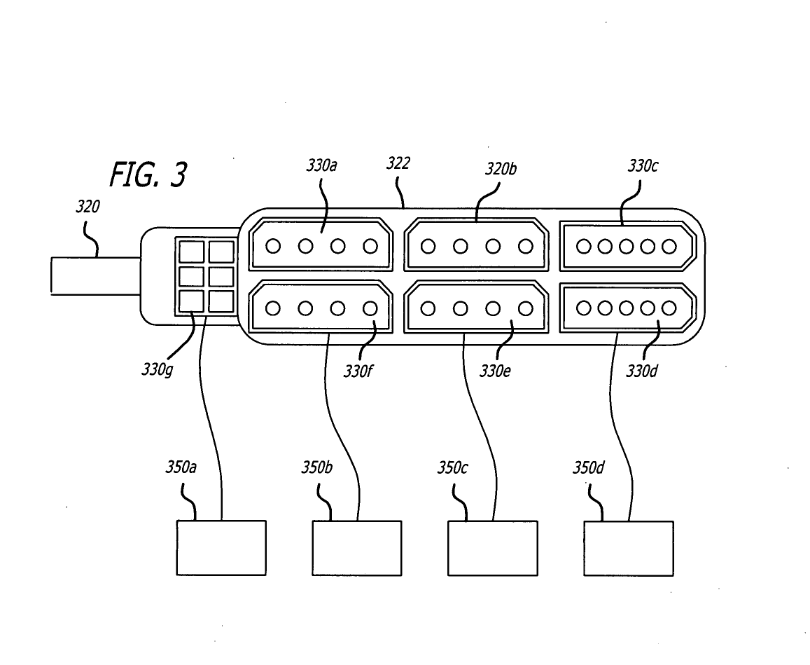

FIG. 3 illustrates a top view of an end of a wiring harness cable in accordance with one embodiment of the present invention. As shown, wiring harness 320 provides a power distribution panel 322 having power connection points 330a-g. One or more electrical components 350a-d connect to the power connection points 330a-g for transferring electrical power from a power supply, such as power supply module shown in FIG. 2, through the wiring harness 320 to the one or more electrical components 350a-d.

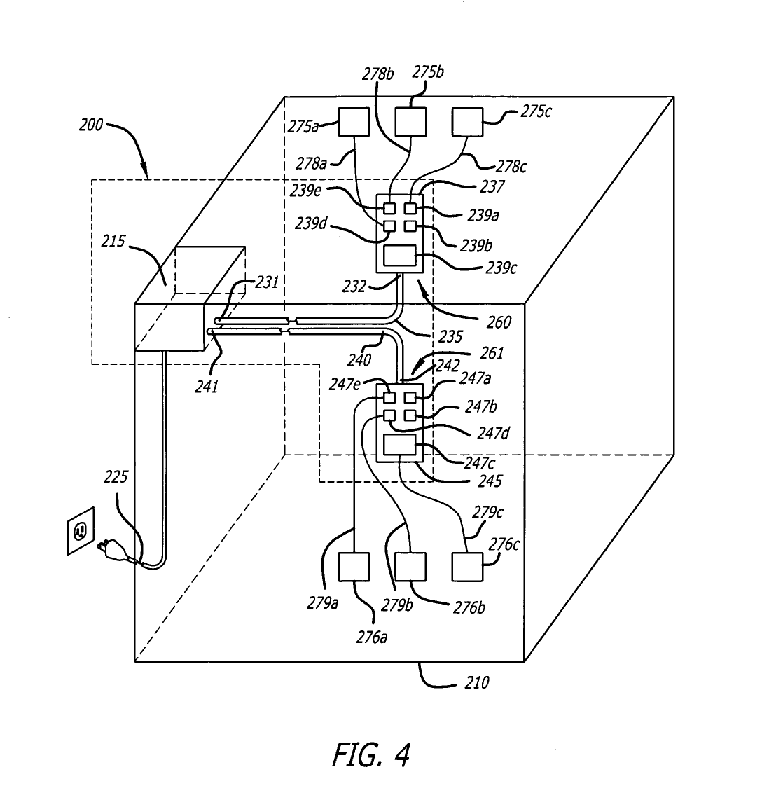

FIG. 4 illustrates a power supply apparatus having a first and a second power distribution panel connected to a first sub-wiring harness cable 235 and a second sub-wiring harness cable 240, respectively, in accordance with one embodiment of the present invention. As shown, a power supply apparatus 200 provides power to electrical components, for example, circuit cards 275a-c and 276a-c, located inside a computer housing 210.

A power supply module 215 inside of the computer housing 210, in one example, converts an ac power level to at least one dc power level. The power supply module 215 is preferably a switching power supply. A first power distribution panel 237 is preferably disposed at a first end 232 of a first sub-wiring harness 235. A second end 231 of the first sub-wiring harness 235 preferably electrically couples to the power supply module 215. The first sub-wiring harness 235 transfers, in one preferred embodiment, the at least one dc power level to the first power distribution panel 237. In another preferred embodiment, the first sub-wiring harness 235 transfers more than one power level to the first power distribution panel 237.

A second power distribution panel 245 disposed preferably at a first end 242 of the second sub-wiring harness 240 inside of the computer housing 210. The second sub-wiring harness 240 electrically couples preferably at a second end 241 of the second sub-wiring harness 240 to the power supply module 215. The power supply module 215 provides the at least one dc power level to a second power distribution panel 245.

A first group of electrical components, for example circuit cards 275a-c, may be preferably connected by electrical cables 278a-c to the first power distribution panel 237. A second group of electrical components, for example circuit cards 276a-c, may be preferably connected, by electrical cables 279a-c to the second power distribution panel 245.

The first power distribution panel 237 and the second power distribution panel 245 may be located to distribute, in yet another example, one or more power levels, to various electrical components. The first and second power distribution panels 237 and 245, for example, may be located to reduce the length of cables, for example 278a-c and 279a-c, respectively, to provide electrical power between the first and second power distribution panels 237 and 245 and the circuit cards 275a-c and/or 276a-c, respectively. This reduction in cable lengths results in reduced electrical wire and/or cable clutter within the computer housing 210.

Furthermore, the first and the second power distribution panels 237 and 245 prevent loose, unconnected cables from being present in the computer housing 210 because cables are only provided to the first and second power distribution panels 237 and 245 if there are electrical components for coupling to the first and the second power distribution panels 237 and 245. In addition, the first and second power distribution panels 237 and 245, located away from the power supply 215, allow the power supply 215 to occupy a smaller space so as to increase the free space within the computer housing 210.

Preferably, the first power distribution panel 237 provides a first set of electrical adaptors 239a-e to transfer one or more power levels to the circuit cards 275a-c. Preferably, the second power distribution panel 245 provides a second set of electrical adaptors 247a-e to transfer electrical power through cables to circuit cards 276a-e. The first set of electrical adaptors 239a-e may comprise multiple adaptor sizes and types. The second set of electrical adaptors 247a-e may comprise multiple adaptor sizes and types.

In yet another example, the first set of electrical adaptors 239a-e and the second set of electrical adaptors 247a-e comprise distinctive adaptor sizes and types. The at least one of the first set of electrical adaptors 239a-e and/or the second set of electrical adaptors 247a-e are integrally formed and monolithically integrated, in one preferred embodiment, in the first power distribution panel 237 and the second power distribution panel 245, respectively.

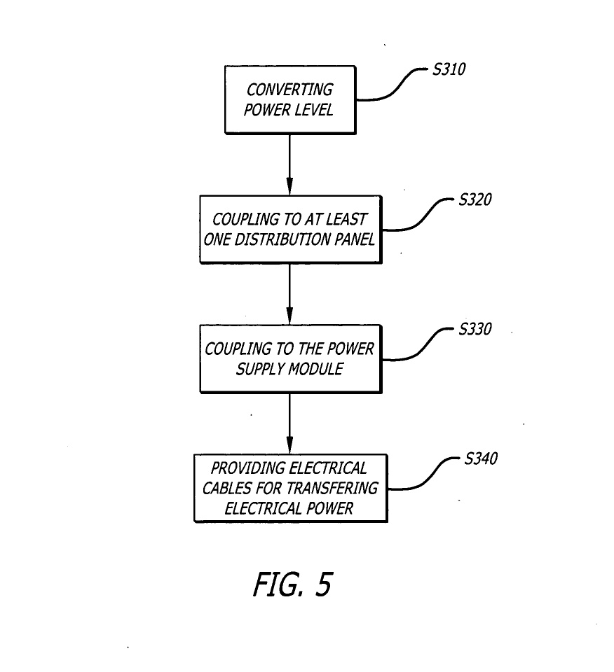

As shown in FIG. 5, a method is disclosed that provides power to a plurality of electrical components while decreasing cable and/or wire clutter within an electrical housing. The method comprises converting electrical power to at least one power level using a power supply module (S310). The method further comprises electrically coupling at least one power distribution panel to a first end of at least one wiring harness (S320).

The method further comprises electrically coupling a second end of the at least one wiring harness to the power supply module for transferring the at least one power level through the at least one wiring harness to electrical adaptors disposed within the at least one power distribution panel (S330). The method further comprises coupling electrical cables between the plurality of electrical components and the electrical adaptors for transferring the at least one power level from the power supply module to the plurality of electrical components (S340).

The at least one power distribution panel provides electrical adapters to transfer the at least one power level to the plurality of electrical components. The electrical adaptors comprise multiple sizes and types of adaptors. The electrical adaptors comprise multiple plug-in cable connectors. The electrical adaptors are integrally formed and monolithically integrated with the at least one power distribution panel.

As the present invention may be embodied in several forms without departing from the spirit or essential characteristics thereof, it should also be understood that the above-described embodiments are not limited by any of the details of the foregoing description, unless otherwise specified. The above-described embodiments rather should be construed broadly within its spirit and scope as defined in the appended claims, and therefore all changes and modifications that fall within the metes and bounds of the claims, or equivalence of such metes and bounds are therefore intended to be embraced by the appended claims.

What is claimed is:

1. A power supply apparatus to provide power to a plurality of electrical components inside a computer housing, the power supply apparatus comprising:
a power supply module to convert electrical power to at least one power level;
at least one power distribution panel disposed within the computer housing; and
at least one wiring harness electrically coupled at a first end of the at least one wiring harness to the at least one power distribution panel and at a second end of the at least one wiring harness to the power supply module to transfer the at least one power level to the at least one power distribution panel,
wherein the at least one power distribution panel provides electrical adapters to transfer the at least one power level through cables that are coupled between the electrical adaptors and the plurality of electrical components.

2. The apparatus of claim 1, wherein the electrical adaptors comprise multiple sizes and types of adaptors.

3. The apparatus of claim 1, wherein the electrical adaptors comprise multiple plug-in cable connectors.

4. The apparatus of claim 1, wherein the electrical adaptors are integrally formed and monolithically integrated within the at least one power distribution panel.

5. The apparatus of claim 1, wherein the power supply module is a switching power supply.

6. A power supply apparatus to provide power to a first plurality of electrical components and second plurality of electrical components inside of a computer housing, the power supply apparatus comprising:
a power supply module to provide at least one power level;
a first power distribution panel having a first set of electrical adaptors and disposed inside the computer housing;
a first sub-wiring harness electrically coupled at a first end of the first sub-wiring harness to the first power distribution panel and at a second end of the first sub-wiring harness to the power supply module;
a second power distribution panel having a second set of electrical adaptors and disposed inside the computer housing; and
a second sub-wiring harness electrically coupled at a first end of the second sub-wiring harness to the second power distribution panel and at a second end of the second sub-wiring harness to the power supply module.

7. The apparatus of claim 6, further comprising a first plurality of cables connected between the first set of electrical adaptors disposed on the first power distribution panel and the first plurality of electrical components to transfer the at least one power level from the power supply module to the first plurality of electrical components.

8. The apparatus of claim 7, further comprising a second plurality of cables connected between the second set of electrical adapters disposed on the second power distribution panel and the second plurality of electrical components to transfer the at least one power level from the power supply to the second plurality of electrical components.

9. The apparatus of claim 6, wherein the first set of electrical adaptors comprise multiple sizes and types of adaptors.

10. The apparatus of claim 6, wherein the second set of electrical adaptors comprise multiple sizes and types of adaptors.

11. The apparatus of claim 6, wherein the first set of electrical adaptors and the second set of electrical adaptors comprise distinctive sizes and types.

12. The apparatus of claim 6, wherein the first set of electrical adaptors and the second set of electrical adaptors are integrally formed and monolithically integrated within the first power distribution panel and the second power distribution panel, respectively.

13. The apparatus of claim 6, wherein the power supply module is a switching power supply.

14. A method of providing power to a plurality of electrical components while decreasing cable and/or wire clutter within an electrical housing, the method comprising:
converting electrical power to at least one power level using a power supply module;
electrically coupling at least one power distribution panel to a first end of at least one wiring harness;
electrically coupling a second end of the at least one wiring harness to the power supply module for transferring the at least one power level through the at least one wiring harness to electrical adaptors disposed within the at least one power distribution panel; and
coupling electrical cables between the plurality of electrical components and the electrical adaptors within the at least one power distribution panel for transferring the at least one power level from the power supply module to the plurality of electrical components.

15. The method of claim 14, wherein the electrical adaptors comprise multiple sizes and types of adaptors.

16. The method of claim 14, wherein the electrical adaptors comprise multiple plug-in cable connectors.

17. The method of claim 15, wherein the electrical adaptors are integrally formed and monolithically integrated within the at least one power distribution panel.

18. The method of claim 17, wherein a first power distribution panel is electrically coupled to a first end of a first wiring harness and a second power distribution panel is electrically coupled to a first end of a second wiring harness, and a second end of the first wiring harness and a second end of the second wiring harness electrically coupled to the power supply module.

19. The method of claim 17, wherein the electrical power is converted to two power levels.

20. The method of claim 17, wherein the power supply module is a switching power supply module.
